(19) United States
(12) Patent Application Publication
(10) Pub. No.: US 2024/0424457 A1
(43) Pub. Date: Dec. 26, 2024

(54) GAS MIXING DEVICE, SUBSTRATE PROCESSING SYSTEM INCLUDING THE SAME, AND SUBSTRATE PROCESSING METHOD USING THE SAME

(71) Applicant: Samsung Electronics Co., Ltd., Suwon-si (KR)

(72) Inventors: Hyunjoong Kim, Suwon-si (KR); Sebin Choi, Suwon-si (KR); Myeongjun Gil, Suwon-si (KR); Sunghyup Kim, Suwon-si (KR); Sunjoo Lee, Suwon-si (KR); Cheol-Jae Lee, Suwon-si (KR); Donghwy Chin, Suwon-si (KR); Donghee Han, Suwon-si (KR)

(21) Appl. No.: 18/393,917

(22) Filed: Dec. 22, 2023

(30) Foreign Application Priority Data
Jun. 23, 2023 (KR) 10-2023-0081268

(51) Int. Cl. B01F 25/314; B01F 23/10; B01F 25/31

(52) U.S. Cl. CPC B01F 25/3143; B01F 23/10; B01F 25/311

(57) ABSTRACT

A gas mixing device may include a main conduit and a gas transferring device connected to the main conduit. The gas transferring device may include a distribution device surrounding the main conduit, a supplying conduit connected to the distribution device and defining a supplying path, and a plurality of connection conduits connecting the first distribution device to the main conduit. The distribution device may include inner and outer cylinders, which are sequentially provided to surround the main conduit and are sequentially spaced apart from the main conduit in a radial direction. A distribution space may be defined between the inner and outer cylinders, and the supplying conduit may be coupled to the outer cylinder, such that the supplying path is connected to the distribution space. The connection conduits may be spaced apart from each other in a circumferential direction.

### CROSS-REFERENCE TO RELATED APPLICATIONS

This U.S. non-provisional patent application claims priority under 35 U.S.C. § 119 to Korean Patent Application No. 10-2023-0081268, filed on Jun. 23, 2023, in the Korean Intellectual Property Office, the entire contents of which are hereby incorporated by reference.

### BACKGROUND

The present disclosure relates to a gas mixing device, a substrate processing system including the same, and a substrate processing method using the same, and in particular, to a gas mixing device, which is configured to mix two or more gases, a substrate processing system including the same, and a substrate processing method using the same.

A process of fabricating a semiconductor device includes various processes. For example, the semiconductor device may be fabricated through a photolithography process, an etching process, a deposition process, and a plating process. A gas may be utilized in the process to fabricate the semiconductor device. For example, in an atomic layer deposition (ALD) process, a gas may be supplied to a region on a substrate. In general, two or more gases may be used for each process. The two or more gases may be mixed with each other and then may be supplied to a region on the substrate.

### SUMMARY

Embodiments of the inventive concept provide a gas mixing device, which is configured to effectively mix two or more gases, a substrate processing system including the same, and a substrate processing method using the same.

Embodiments of the inventive concept provide a gas mixing device, which is configured to prevent two or more gases from reacting with each other therein and prevent particles from being formed, a substrate processing system including the same, and a substrate processing method using the same.

Embodiments of the inventive concept provide a gas mixing device, which is configured to uniformly supply a gas, a substrate processing system including the same, and a substrate processing method using the same.

Embodiments of the inventive concept provide a gas mixing device, in which conductance of a conduction path or flow path is controlled to achieve a smooth gas flow, a substrate processing system including the same, and a substrate processing method using the same.

According to some embodiments of the inventive concept, a gas mixing device may include a main conduit defining a main path extending in a first direction, and a first gas transferring device connected to the main conduit. The first gas transferring device may include a first distribution device surrounding the main conduit, a first supplying conduit connected to the first distribution device and defining a first supplying path, and a plurality of first connection conduits connecting the first distribution device to the main conduit. The first distribution device may include a first inner cylinder surrounding the main conduit and spaced apart from the main conduit in a radial direction, and a first outer cylinder surrounding the first inner cylinder and spaced apart from the first inner cylinder in a radial direction. A first distribution space may be defined between the first inner cylinder and the first outer cylinder, and the first supplying conduit may be coupled to the first outer cylinder, such that the first supplying path is connected to the first distribution space. The first connection conduits may be spaced apart from each other in a circumferential direction.

According to some other embodiments of the inventive concept, a gas mixing device may include a main conduit extending in a vertical direction and a first gas transferring device connected to the main conduit. The first gas transferring device may include a first distribution device surrounding the main conduit, a first supplying conduit connected to an outer side surface of the first distribution device and defining a first supplying path, and a plurality of first connection conduits connecting the first distribution device to the main conduit. The first distribution device may include a first inner cylinder surrounding the main conduit and a first outer cylinder surrounding the first inner cylinder and spaced apart from the first inner cylinder. A first distribution space may be defined between the first inner cylinder and the first outer cylinder. A first height of the first distribution space may be at least three times greater than a first diameter of the first supplying path.

According to some other embodiments of the inventive concept, a gas mixing device may include a main conduit connecting a first gas supplying device to a substrate processing device, and a first gas transferring device connected to the main conduit. The first gas transferring device may include a first distribution device surrounding the main conduit, a first supplying conduit connecting a second gas supplying device to the first distribution device, and a plurality of first connection conduits connecting the first distribution device to the main conduit. The first distribution device may include a first inner cylinder surrounding the main conduit and a first outer cylinder surrounding the first inner cylinder and spaced apart from the first inner cylinder in a radial direction. The first connection conduits may be spaced apart from each other in a circumferential direction.

According to some other embodiments of the inventive concept, a substrate processing system may include a substrate processing device and a gas supplying system connected to the substrate processing device. The gas supplying system may include a first gas supplying device, a second gas supplying device, and a gas mixing device configured to mix a first gas and a second gas, which are respectively supplied from the first gas supplying device and the second gas supplying device, and to supply the mixed gases to the substrate processing device. The gas mixing device may include a main conduit connecting the first gas supplying device to the substrate processing device and a first gas transferring device connected to the main conduit. The first gas transferring device may include a first distribution device surrounding the main conduit, a first supplying conduit connecting the second gas supplying device to the first distribution device, and a plurality of first connection conduits connecting the first distribution device to the main conduit. The first distribution device may include a first inner cylinder surrounding the main conduit and a first outer cylinder surrounding the first inner cylinder and is spaced apart from the first inner cylinder in a radial direction. The first connection conduits may be spaced apart from each other in a circumferential direction.

According to some other embodiments of the inventive concept, a substrate processing method may include positioning a substrate in a substrate processing device and supplying a gas to the substrate processing device. The supplying the gas to the substrate processing device may include supplying the gas in a first mode. The supplying the gas in the first mode may include supplying a first gas from a first gas supplying device, supplying a second gas from a second gas supplying device, mixing the gases in a gas mixing device, and supplying the mixed gases to a space on the substrate. The gas mixing device may include a main conduit connecting the first gas supplying device to the substrate processing device and a first gas transferring device connected to the main conduit. The first gas transferring device may include a first distribution device surrounding the main conduit, a first supplying conduit connecting the second gas supplying device to the first distribution device, and a plurality of first connection conduits connecting the first distribution device to the main conduit. The first distribution device may include a first inner cylinder surrounding the main conduit and a first outer cylinder surrounding the first inner cylinder and spaced apart from the first inner cylinder in a radial direction.

### BRIEF DESCRIPTION OF THE DRAWINGS

FIG. 1 is a schematic diagram illustrating a substrate processing system according to some embodiments of the inventive concept.

FIG. 2 is a perspective view illustrating a gas mixing device according to some embodiments of the inventive concept.

FIG. 3 is a perspective view illustrating a gas mixing device according to some embodiments of the inventive concept.

FIG. 4 is a sectional view illustrating a gas mixing device according to some embodiments of the inventive concept.

FIG. 5 is a sectional view illustrating a gas mixing device according to some embodiments of the inventive concept.

FIG. 6 is a plan view illustrating a gas mixing device according to some embodiments of the inventive concept.

FIG. 7 is a sectional view illustrating a gas mixing device according to some embodiments of the inventive concept.

FIG. 8 is a flow chart illustrating a substrate processing method according to some embodiments of the inventive concept.

FIGS. 9 to 15 are diagrams illustrating a substrate processing method according to the flow chart of FIG. 8.

FIG. 16 is a perspective view illustrating a gas mixing device according to some embodiments of the inventive concept.

FIG. 17 is a perspective view illustrating a gas mixing device according to some embodiments of the inventive concept.

FIG. 18 is a sectional view illustrating a gas mixing device according to some embodiments of the inventive concept.

### DETAILED DESCRIPTION

Example embodiments of the inventive concept will now be described more fully with reference to the accompanying drawings, in which example embodiments are shown. Like reference numerals in the drawings denote like elements, and thus their repeated description may be omitted in the interest of brevity.

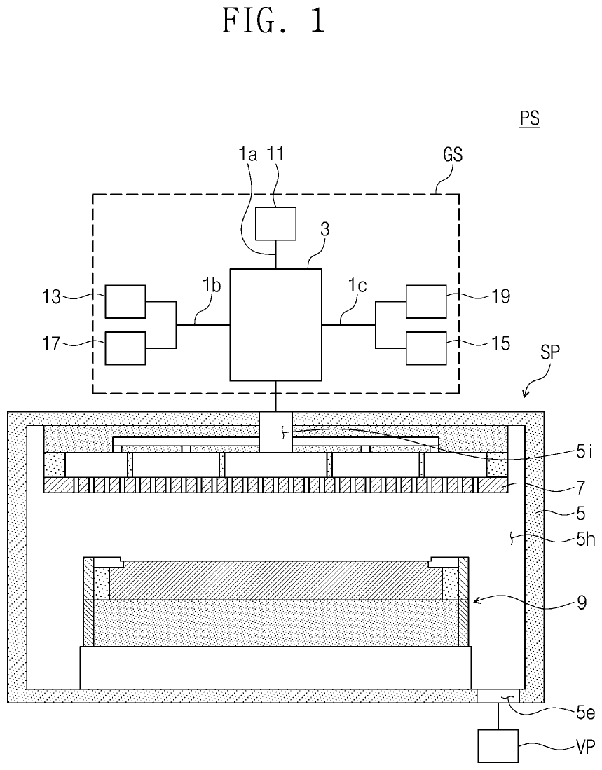

FIG. 1 is a schematic diagram illustrating a substrate processing system according to some embodiments of the inventive concept.

Referring to FIG. 1, a substrate processing system PS may be provided. The substrate processing system PS may be configured to process a substrate. In the present specification, the term ‘substrate’ may mean a silicon wafer, but the inventive concept is not limited to this example. In some embodiments, the substrate processing system PS may be configured to process one substrate at a time. For example, the substrate processing system PS may be configured to perform a deposition process on the substrate. More specifically, the substrate processing system PS may be configured to perform an atomic layer deposition (ALD) process on the substrate. However, the inventive concept is not limited to this example, and the substrate processing system PS may be configured to perform a different process on the substrate. In some embodiments, the substrate processing system PS may include a chamber, in which the process is performed on a plurality of substrates at the same time. However, for brevity's sake, the description that follows will refer to an example, in which the substrate processing system PS is a single wafer type system. The substrate processing system PS may include a substrate processing apparatus or substrate processing device SP, a vacuum pump VP, and a gas supplying part or gas supplying system GS.

The substrate processing device SP may include a process chamber 5, a chuck 9, and a shower head 7.

The process chamber 5 may provide a process space 5h. The process on the substrate may be performed in the process space 5h. During the process, the process space 5h may be maintained at a substantially vacuum state. For this, the process space 5h may be connected to the vacuum pump VP. The process space 5h may further provide or include an injection hole 5i and an exhaustion hole 5e. The process space 5h may be connected to the gas supplying part GS through the injection hole 5i. The process space 5h may be connected to the vacuum pump VP through the exhaustion hole 5e.

The chuck 9 may be placed in the process space 5h. The chuck 9 may be configured to support and/or fasten the substrate. For this, the chuck 9 may include an electrostatic chuck (ESC). However, the inventive concept is not limited to this example, and in some embodiments, the chuck 9 may include a vacuum chuck and/or a clamp. The process may be performed on the substrate that is loaded on the chuck 9. The shower head 7 may be spaced apart from the chuck 9 in an upward direction.

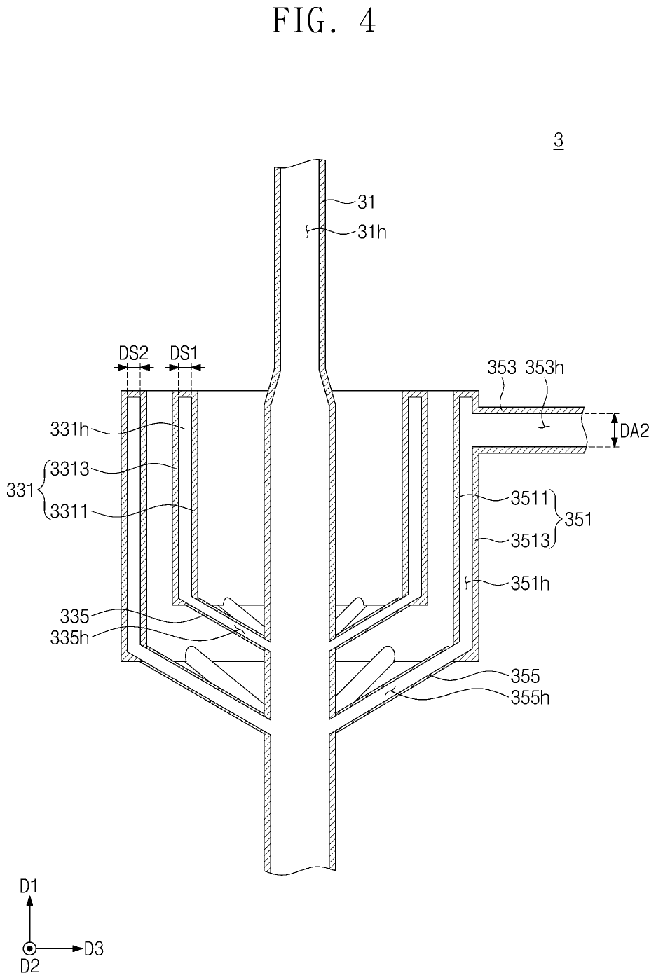

The shower head 7 may be provided to have a plurality of spray holes. Due to the shower head 7, a process gas may be uniformly distributed on the chuck 9. More specifically, the process gas, which is supplied in a space in or on the shower head 7, may be uniformly distributed on the chuck 9 through the spray holes of the shower head 7. For this, the space on the shower head 7 may be connected to the gas supplying part GS. More specifically, the space on the shower head 7 may be connected to a main conduit 31 (e.g., see FIG. 4).

The vacuum pump VP may be connected to the process chamber 5. The inner pressure of the process space 5h may be lowered to the substantially vacuum level by the vacuum pump VP.

The gas supplying part GS may be connected to the substrate processing device SP. The gas supplying part GS may supply the process gas to the substrate processing device SP. In some embodiments, the gas supplying part GS may be configured to supply at least two kinds of gases to the substrate processing device SP. For this, the gas supplying part GS may include a first gas supplying device or first gas supply 11, a second gas supplying device or second gas supply 13, a third gas supplying device or third gas supply 15, a fourth gas supplying device or fourth gas supply 17, a fifth gas supplying device or fifth gas supply 19, a gas mixing device 3, a first conduit 1a, a second conduit 1b, and a third conduit 1c.

The first gas supplying device 11 may be configured to hold and supply a first gas. To do this, the first gas supplying device 11 may include a gas tank and a compressor. The first gas may be, for example, a carrier gas and/or a purge gas. For this, the first gas may include an inert gas. For example, the first gas may include nitrogen (N₂) gas and/or argon (Ar) gas, but the inventive concept is not limited to this example. The first gas supplying device 11 may be connected to the gas mixing device 3. More specifically, the first gas supplying device 11 may be connected to the gas mixing device 3 through the first conduit 1a.

The second gas supplying device 13 may be configured to hold and supply a second gas. To do this, the second gas supplying device 13 may include a gas tank and a compressor. The second gas may include a reactive gas. For example, the second gas may include TiCl₄ gas, NH₃ gas and/or C₆H₁₈Al₂ gas, but the inventive concept is not limited to this example. The second gas supplying device 13 may be connected to the gas mixing device 3. More specifically, the second gas supplying device 13 may be connected to the gas mixing device 3 through the second conduit 1b.

The third gas supplying device 15 may be configured to hold and supply a third gas. To do this, the third gas supplying device 15 may include a gas tank and a compressor. For example, the third gas may be a carrier gas and/or a purge gas. For this, the third gas may include an inert gas. For example, the third gas may include nitrogen (N₂) gas and/or argon (Ar) gas. In other words, the third gas may contain a gas that is of the same kind as the first gas. However, the inventive concept is not limited to this example. The third gas supplying device 15 may be connected to the gas mixing device 3. More specifically, the third gas supplying device 15 may be connected to the gas mixing device 3 through the third conduit 1c.

The fourth gas supplying device 17 may be configured to hold and supply a fourth gas. To do this, the fourth gas supplying device 17 may include a gas tank and a compressor. In some embodiments, the fourth gas may be a carrier gas and/or a purge gas. For this, the fourth gas may include an inert gas. For example, the fourth gas may include nitrogen (N₂) gas and/or argon (Ar) gas. In other words, the fourth gas may contain a gas that is of the same kind as the first gas. However, the inventive concept is not limited to this example. The fourth gas supplying device 17 may be connected to the gas mixing device 3. More specifically, the fourth gas supplying device 17 may be connected to the gas mixing device 3 through the second conduit 1b. In other words, both of the second and fourth gas supplying devices 13 and 17 may be connected to the gas mixing device 3 through the same conduit.

The fifth gas supplying device 19 may be configured to hold and supply a fifth gas. To do this, the fifth gas supplying device 19 may include a gas tank and a compressor. The fifth gas may include a reactive gas. For example, the fifth gas may include TiCl₄ gas, NH₃ gas and/or C₆H₁₈Al₂ gas. However, the fifth gas and the second gas may be of different kinds. The fifth gas supplying device 19 may be connected to the gas mixing device 3. More specifically, the fifth gas supplying device 19 may be connected to the gas mixing device 3 through the third conduit 1c. In other words, both of the third and fifth gas supplying devices 15 and 19 may be connected to the gas mixing device 3 through the same conduit.

The gas mixing device 3 may be configured to mix gases of at least two kinds. For this, the gas mixing device 3 may be connected to the first gas supplying device 11, the second gas supplying device 13, the third gas supplying device 15, the fourth gas supplying device 17 and the fifth gas supplying device 19. In addition, the gas mixing device 3 may supply the mixed gases to the substrate processing device SP. For this, the gas mixing device 3 may be connected to the substrate processing device SP. The gas mixing device 3 will be described in more detail below.

The first conduit 1a may connect the first gas supplying device 11 to the gas mixing device 3.

The second conduit 1b may connect each of the second and fourth gas supplying devices 13 and 17 to the gas mixing device 3.

The third conduit 1c may connect each of the third and fifth gas supplying devices 15 and 19 to the gas mixing device 3.

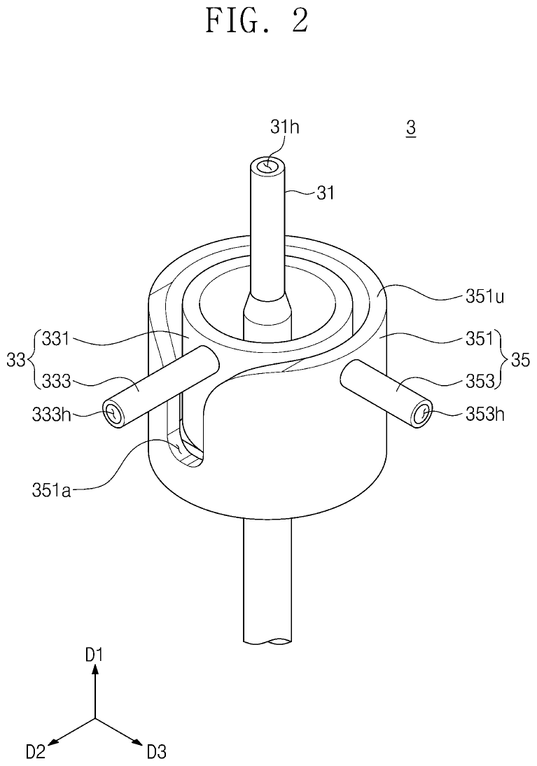

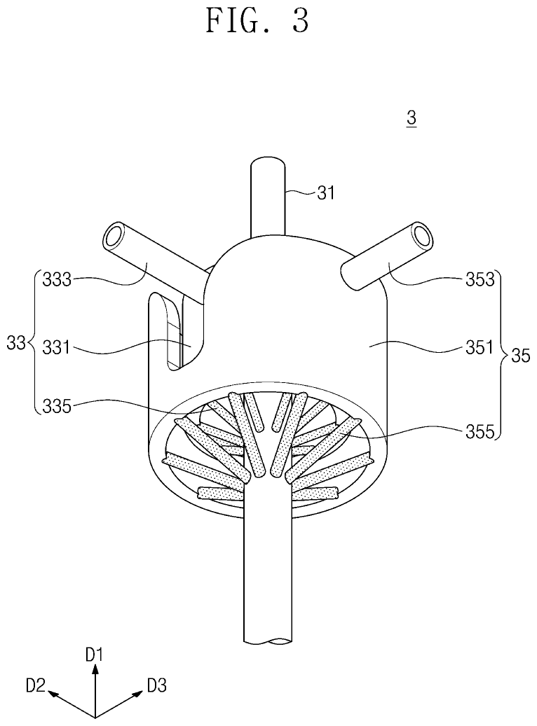

FIG. 2 is a perspective view illustrating a gas mixing device according to some embodiments of the inventive concept, and FIG. 3 is a perspective view illustrating a gas mixing device according to some embodiments of the inventive concept.

In the present application, the reference numbers D1, D2, and D3 will be used to denote a first direction, a second direction, and a third direction, respectively, which are not parallel to each other. The first direction D1 may be referred to as a vertical or upward direction. In addition, each of the second and third directions D2 and D3 may be referred to as a horizontal direction. The first, second, and third directions D1, D2 and D3 may be orthogonal to each other, but the inventive concept is not limited to this example.

Referring to FIGS. 2 and 3, the gas mixing device 3 may include the main conduit 31, a first gas transferring device or inner gas transferring device 33, and a second gas transferring device or outer gas transferring device 35.

The main conduit 31 may provide a main path or main channel 31h. The main path 31h may be extended in the first direction D1. The main conduit 31 may be connected to the substrate processing device SP (e.g., see FIG. 1). More specifically, the main conduit 31 may be connected to a space on or in the shower head 7 (e.g., see FIG. 1). The main conduit 31 may be connected to the first conduit 1a (e.g., see FIG. 1). That is, the main conduit 31 may connect the first conduit 1a to the substrate processing device SP. Alternatively, the main conduit 31 and the first conduit 1a may form a single or unitary object. The first gas, which is supplied from the first gas supplying device 11 (e.g., see FIG. 1), may be transferred to the substrate processing device SP along the main conduit 31.

The first gas transferring device 33 may be connected to the main conduit 31. The first gas transferring device 33 may be connected to the second conduit 1b (e.g., see FIG. 1). In other words, the first gas transferring device 33 may connect the second conduit 1b to the main conduit 31. The gas in the second conduit 1b may be transferred to the main conduit 31 through the first gas transferring device 33. To do this, the first gas transferring device 33 may include a first distribution device 331, a first supplying conduit 333, and a first connection conduit 335.

The first distribution device 331 may be provided to at least partially enclose or surround the main conduit 31. For example, the first distribution device 331 may be spaced apart from the main conduit 31. More specifically, the first distribution device 331 may be spaced apart from the main conduit 31 in a radial direction. The first distribution device 331 may have a circular shape, when viewed in a plan view. The first distribution device 331 may be extended in the first direction D1 by a specific length. That is, the first distribution device 331 may have a cylindrical shape. A first distribution space 331h (e.g., see FIG. 4) may be provided in the first distribution device 331. The first distribution device 331 will be described in more detail below.

The first supplying conduit 333 may be connected to the first distribution device 331. For example, the first supplying conduit 333 may be connected to an outer side surface of the first distribution device 331. The first supplying conduit 333 may be connected to the second conduit 1b (e.g., see FIG. 1). That is, the second conduit 1b and the first distribution device 331 may be connected to each other by the first supplying conduit 333. Alternatively, the first supplying conduit 333 and the second conduit 1b may form a single or unitary object. The first supplying conduit 333 will be described in more detail below.

The first connection conduit 335 may connect the first distribution device 331 to the main conduit 31. In some embodiments, a plurality of first connection conduits 335 may be provided. The first connection conduits 335 may be disposed to be spaced apart from each other in a radial or circumferential direction. For example, the first gas transferring device 33 may be provided to include eight first connection conduits 335. However, in order to reduce complexity in the description, the description that follows will refer to an example in which the first gas transferring device 33 includes one first connection conduit 335, unless the context clearly indicates otherwise.

The second gas transferring device 35 may be connected to the main conduit 31. The second gas transferring device 35 may be connected to the third conduit 1c (e.g., see FIG. 1). That is, the second gas transferring device 35 may connect the third conduit 1c to the main conduit 31. The gas in the third conduit 1c may be transferred to the main conduit 31 through the second gas transferring device 35. For this, the second gas transferring device 35 may include a second distribution device 351, a second supplying conduit 353, and a second connection conduit 355.

The second distribution device 351 may be provided to at least partially enclose or surround the main conduit 31 and the first distribution device 331. For example, the second distribution device 351 may be spaced apart from the first distribution device 331. More specifically, the second distribution device 351 may be spaced apart from the first distribution device 331 in a radial direction. The second distribution device 351 may have a circular shape, when viewed in a plan view. The second distribution device 351 may be extended in the first direction D1 by a specific length. That is, the second distribution device 351 may have a cylindrical shape. A second distribution space 351h (e.g., see FIG. 4) may be provided in the second distribution device 351.

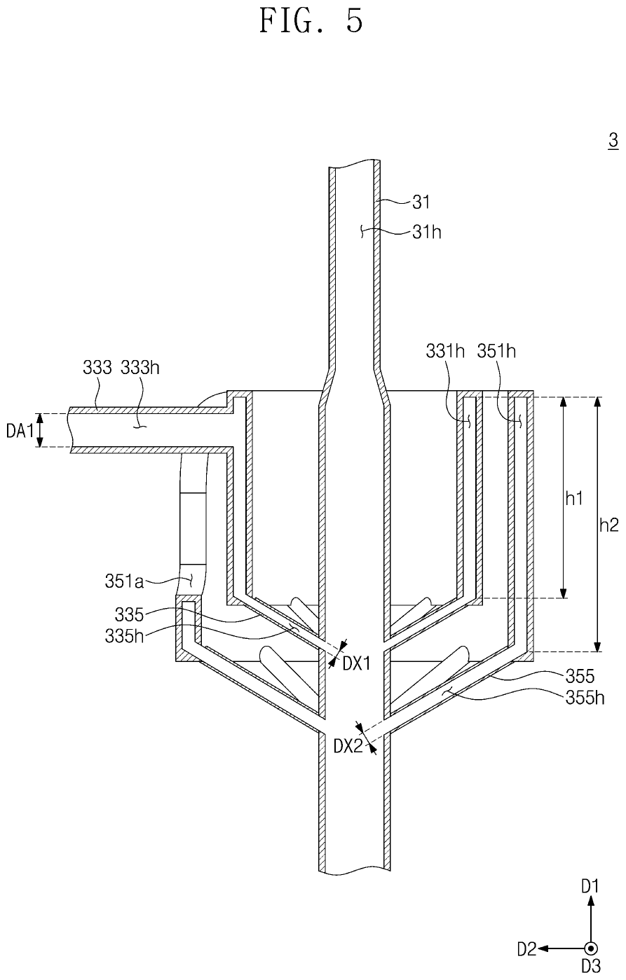

The second distribution device 351 may further provide a connection hole or connection slot 351a. The connection hole 351a may be formed to have a shape that is recessed downward from a top surface 351u of the second distribution device 351. The first supplying conduit 333 may be connected to the first distribution device 331 through the connection hole 351a. The connection hole 351a may not be connected to the second distribution space 351h (e.g., see FIG. 5). The second distribution device 351 will be described in more detail below.

The second supplying conduit 353 may be connected to the second distribution device 351. For example, the second supplying conduit 353 may be connected to an outer side surface of the second distribution device 351. The second supplying conduit 353 may be connected to the third conduit 1c (e.g., see FIG. 1). That is, the third conduit 1c and the second distribution device 351 may be connected to each other by the second supplying conduit 353. Alternatively, the second supplying conduit 353 and the third conduit 1c may be provided to form a single or unitary object. The second supplying conduit 353 will be described in more detail below.

The second connection conduit 355 may connect the second distribution device 351 to the main conduit 31. In some embodiments, a plurality of second connection conduits 355 may be provided. The second connection conduits 355 may be disposed to be spaced apart from each other in a radial or circumferential direction. For example, the second gas transferring device 35 may be provided to include eight second connection conduits 355. However, in order to reduce complexity in the description, the description that follow will refer to an example in which the second gas transferring device 35 includes one second connection conduit 355, unless the context clearly indicates otherwise.

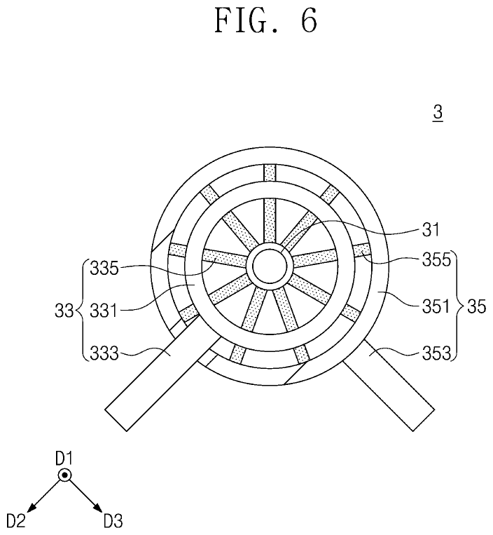

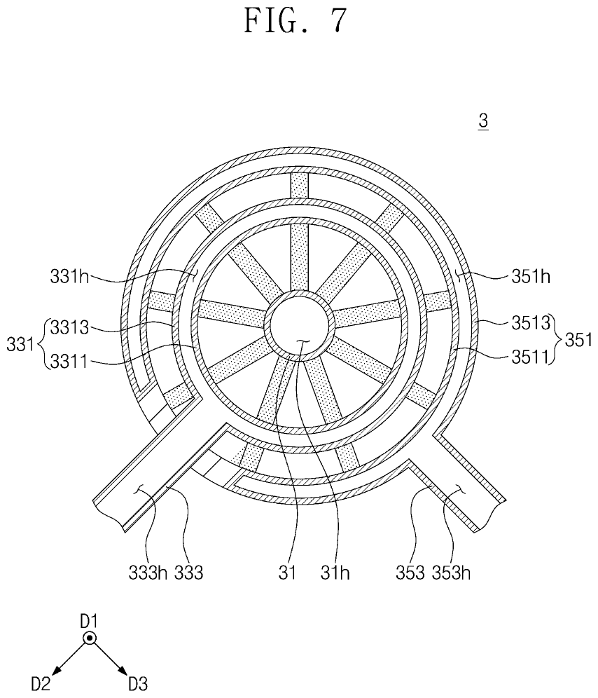

FIG. 4 is a sectional view illustrating a gas mixing device according to some embodiments of the inventive concept, FIG. 5 is a sectional view illustrating a gas mixing device according to some embodiments of the inventive concept, FIG. 6 is a plan view illustrating a gas mixing device according to some embodiments of the inventive concept, and FIG. 7 is a sectional view illustrating a gas mixing device according to some embodiments of the inventive concept.

Referring to FIGS. 4 to 7, the first distribution device 331 may include a first inner cylinder 3311 and a first outer cylinder 3313.

The first inner cylinder 3311 may at least partially enclose or surround the main conduit 31. For example, the first inner cylinder 3311 may be spaced apart from the main conduit 31 in a radial direction. Thus, a length of the first connection conduit 335 may be freely designed. For example, a distance between the first inner cylinder 3311 and the main conduit 31 may be set to realize a length of the first connection conduit 335 for a required value of conductance or resistance of the conduction path or flow path. Thus, the conductance of the conduction path may be controlled to achieve a smooth gas flow.

The first outer cylinder 3313 may be provided to at least partially enclose or surround the first inner cylinder 3311. The first outer cylinder 3313 may be spaced apart from the first inner cylinder 3311 in a radial direction.

The first distribution space 331h may be provided between the first inner cylinder 3311 and the first outer cylinder 3313. The first distribution space 331h may have a ring or annular shape, when viewed in a plan view. A length of the first distribution space 331h in the first direction D1 may be referred to as a first height h1. A length of the first distribution space 331h in a radial direction may be referred to as a first width DS1. The first width DS1 may be the smallest horizontal distance between the first inner cylinder 3311 and the first outer cylinder 3313. An upper end of the first distribution space 331h may be closed. For this, the first distribution device 331 may further include an upper member. In addition, a lower end of the first distribution space 331h may be closed, except for a portion connected to the first connection conduit 335. For this, the first distribution device 331 may further include a lower member.

The first supplying conduit 333 may provide a first supplying path or channel 333h. The first supplying conduit 333 may be coupled to the first outer cylinder 3313. For example, the first supplying conduit 333 may be coupled to an outer side surface of the first outer cylinder 3313. The first supplying path 333h may be connected to the first distribution space 331h. A diameter of the first supplying path 333h may be referred to as a first diameter DAL. An extension direction of the first supplying path 333h may be perpendicular to the first direction D1. Thus, the gas, which is injected into the first distribution space 331h along the first supplying path 333h, may collide with an outer side surface of the first inner cylinder 3311 and may be dispersed in a circumference direction. Thus, the gas, which is injected into the first distribution space 331h, may be smoothly dispersed in a circumference direction.

In some embodiments, the first diameter DA1 may be smaller than the first height h1. For example, the first height h1 may be equal to or greater than about 3 times the first diameter DAL. Thus, the gas, which is injected into the first distribution space 331h along the first supplying path 333h, may be sufficiently dispersed in the first distribution space 331h, before it is exhausted from the main conduit 31 through the first connection conduit 335.

A first injection hole or first injection location, where the first supplying path 333h and the first distribution space 331h meet each other, may be spaced apart from the upper end of the first distribution space 331h in a downward direction. In addition, the first injection hole may be placed at a level that is higher than the center of the first distribution space 331h. Thus, at least a portion of the gas, which is injected into the first distribution space 331h along the first supplying path 333h, may collide with the outer side surface of the first inner cylinder 3311 and may be moved in an upward direction. Thus, the gas in the first distribution space 331h may be sufficiently dispersed in a circumference direction.

The first connection conduit 335 may be linearly extended from the first distribution device 331 toward the main conduit 31. An extension direction of the first connection conduit 335 may be inclined at an acute angle to the first direction D1. The first connection conduit 335 may provide a first connection path 335h. A diameter of the first connection path 335h may be referred to as a first connection diameter DX1. The first connection path 335h may be connected to the first distribution space 331h. The first connection conduit 335 may be connected to a lower end of the first distribution space 331h. An extension direction of the first connection conduit 335 may be inclined at an acute angle to the first direction D1. Thus, the gas in the first distribution space 331h may be effectively exhausted through the first connection conduit 335.

The second distribution device 351 may include a second inner cylinder 3511 and a second outer cylinder 3513.

The second inner cylinder 3511 may be provided to at least partially enclose or surround the first outer cylinder 3313. For example, the second inner cylinder 3511 may be spaced apart from the first outer cylinder 3313 in a radial direction.

The second outer cylinder 3513 may be provided to at least partially enclose or surround the second inner cylinder 3511. The second outer cylinder 3513 may be spaced apart from the second inner cylinder 3511 in a radial direction.

The second distribution space 351h may be provided between the second inner cylinder 3511 and the second outer cylinder 3513. The second distribution space 351h may have a ring or annular shape, when viewed in a plan view. A length of the second distribution space 351h in the first direction D1 may be referred to as a second height h2. A length of the second distribution space 351h in a radial direction may be referred to as a second width DS2. The second width DS2 may be the smallest horizontal distance between the second inner cylinder 3511 and the second outer cylinder 3513. The second width DS2 may be larger than the first width DS1. An upper end of the second distribution space 351h may be closed. For this, the second distribution device 351 may further include an upper end member. In addition, a lower end of the second distribution space 351h may be closed, except for a portion connected to the second connection conduit 355. For this, the second distribution device 351 may further include a lower member.

The second supplying conduit 353 may provide a second supplying path or channel 353h. The second supplying conduit 353 may be coupled to the second outer cylinder 3513. For example, the second supplying conduit 353 may be coupled to an outer side surface of the second outer cylinder 3513. The second supplying path 353h may be connected to the second distribution space 351h. A diameter of the second supplying path 353h may be referred to as a second diameter DA2. An extension direction of the second supplying path 353h may be perpendicular to the first direction D1. Thus, the gas, which is injected into the second distribution space 351h along the second supplying path 353h, may collide with an outer side surface of the second inner cylinder 3511 and may be dispersed in a circumference direction. Thus, the gas, which is supplied into the second distribution space 351h, may be effectively dispersed in a circumference direction. The second supplying conduit 353 may be placed at substantially the same level (e.g., vertical level) as the first supplying conduit 333, but the inventive concept is not limited to this example.

In some embodiments, the second diameter DA2 may be smaller than the second height h2. For example, the second height h2 may be larger than about 3 times the second diameter DA2. Thus, the gas, which is injected into the second distribution space 351h along the second supplying path 353h, may be sufficiently dispersed in the second distribution space 351h, before it is exhausted from the main conduit 31 through the second connection conduit 355. The second diameter DA2 may be larger than the first diameter DA1, but the inventive concept is not limited to this example.

A second injection hole or location, where the second supplying path 353h and the second distribution space 351h meet each other, may be spaced apart from the upper end of the second distribution space 351h in a downward direction. In addition, the second injection hole may be placed at a level that is higher than the center of the second distribution space 351h. Thus, at least a portion of the gas, which is injected into the second distribution space 351h along the second supplying path 353h, may collide with the outer side surface of the second inner cylinder 3511 and may be moved in an upward direction. Accordingly, the gas in the second distribution space 351h may be sufficiently dispersed in a circumference direction.

The second connection conduit 355 may be linearly extended from the second distribution device 351 toward the main conduit 31. An extension direction of the second connection conduit 355 may be inclined at an acute angle to the first direction D1. The second connection conduit 355 may provide a second connection path or channel 355h. A diameter of the second connection path 355h may be referred to as a second connection diameter DX2. A length of the second connection path 355h may be larger than a length of the first connection path 335h. By contrast, the second connection diameter DX2 may be larger than the first connection diameter DX1. Thus, the conductance or resistance of the first connection path 335h may be substantially equal or similar to the conductance or resistance of the second connection path 355h. Alternatively, a difference in conductance between the first and second connection paths 335h and 355h may be relatively small. Thus, it may be possible to achieve a substantially similar gas flow rate, even when the first and second connection paths 335h and 355h are interchangeably used. The second connection path 355h may be connected to the second distribution space 351h. The second connection conduit 355 may be connected to the lower end of the second distribution space 351h. An extension direction of the second connection conduit 355 may be inclined at an acute angle to the first direction D1. Thus, the gas in the second distribution space 351h may be effectively exhausted through the second connection conduit 355.

An upper end of the second distribution device 351 may be at substantially the same level (e.g., vertical level) as an upper end of the first distribution device 331. The second height h2 may be larger than the first height h1. Thus, an upper end of the first connection conduit 335 may be at a higher level (e.g., vertical level) than an upper end of the second connection conduit 355. In addition, a lower end of the first connection conduit 335 may be at a higher level (e.g., vertical level) than a lower end of the second connection conduit 355.

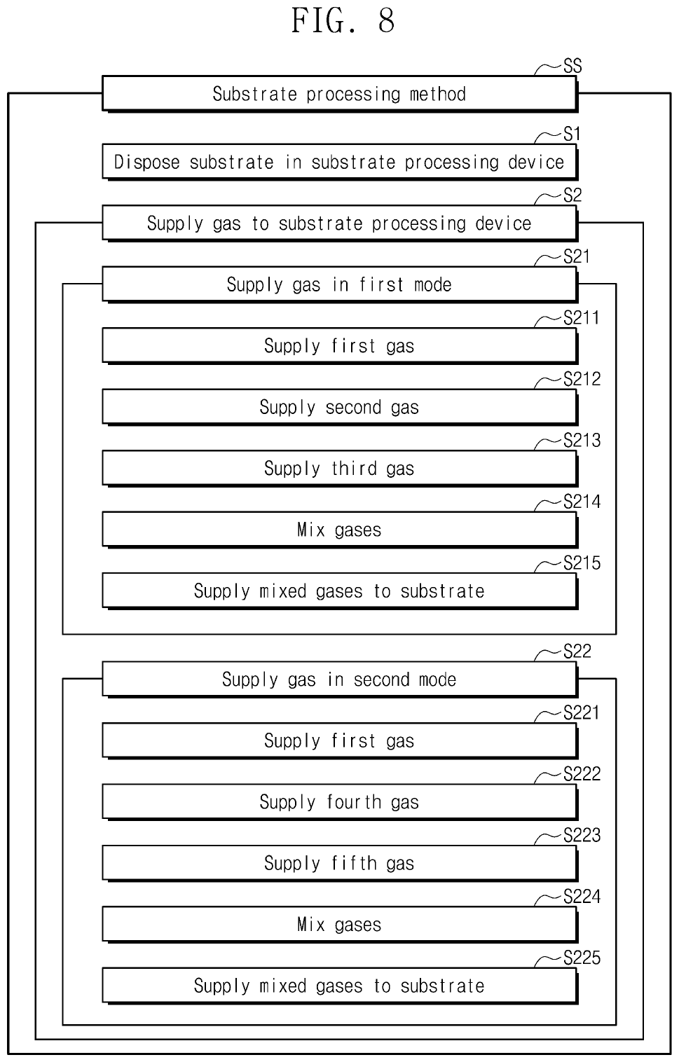

FIG. 8 is a flow chart illustrating a substrate processing method according to some embodiments of the inventive concept.

Referring to FIG. 8, a substrate processing method SS may be provided or performed. The substrate processing method SS may be a method of processing a substrate using the substrate processing system PS described with reference to FIGS. 1 to 7. The substrate processing method SS may include disposing a substrate in a substrate processing device (in S1) and supplying a gas to the substrate processing device (in S2).

The supplying of the gas to the substrate processing device (in S2) may include supplying the gas in a first mode (in S21) and supplying the gas in a second mode (in S22).

The supplying of the gas in the first mode (in S21) may include supplying a first gas (in S211), supplying a second gas (in S212), supplying a third gas (in S213), mixing the gases (in S214), and supplying the mixed gases to a space on the substrate (in S215).

The supplying of the gas in the second mode (in S22) may include supplying the first gas (in S221), supplying a fourth gas (in S222), supplying a fifth gas (in S223), mixing the gases (in S224), and supplying the mixed gases to the space on the substrate (in S225).

The supplying of the gas in the second mode (in S22) may be performed after the suppling of the gas in the first mode (in S21) is finished. That is, the second mode may be performed after the first mode is finished. Alternatively, the first mode and the second mode may be alternately repeated.

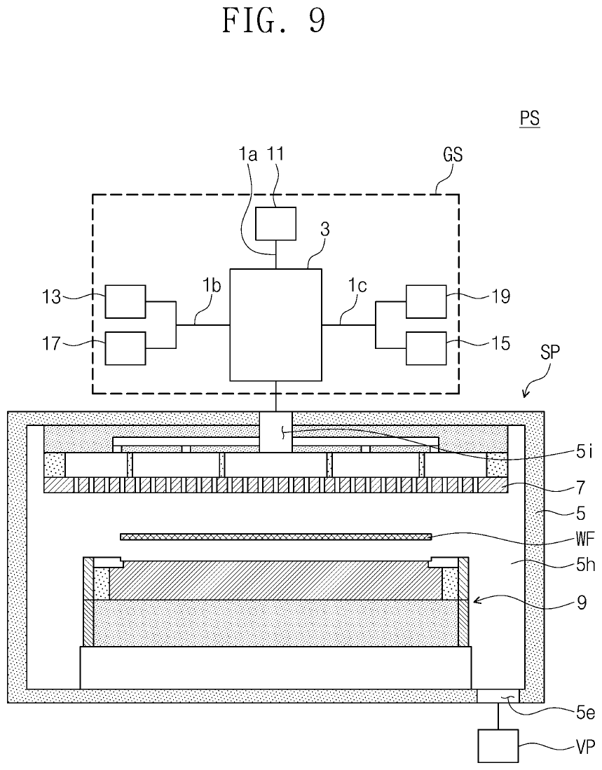

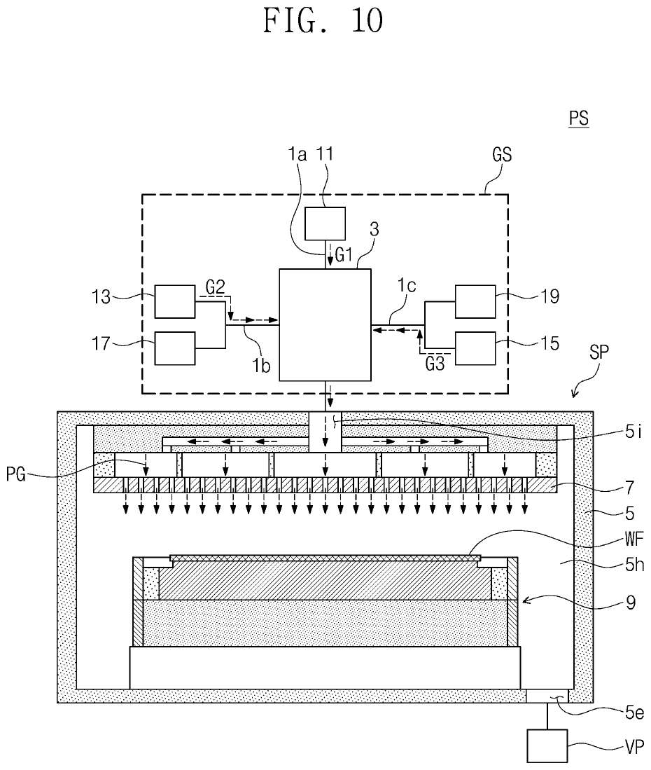

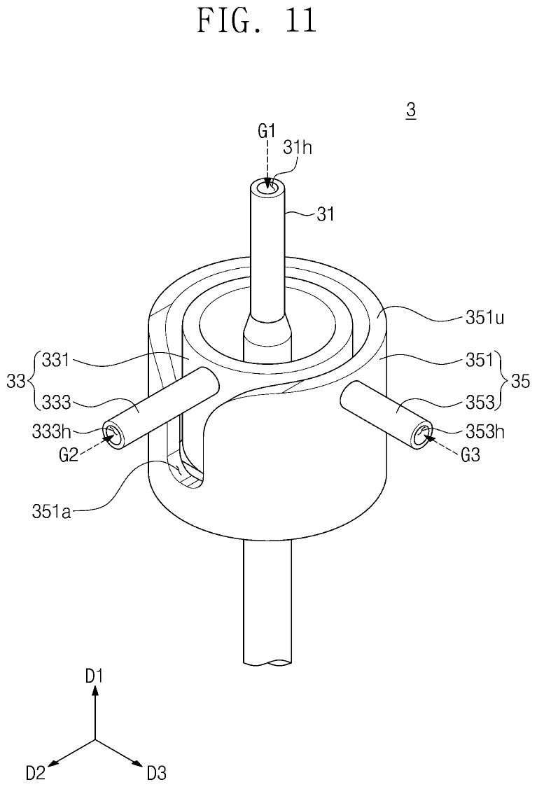

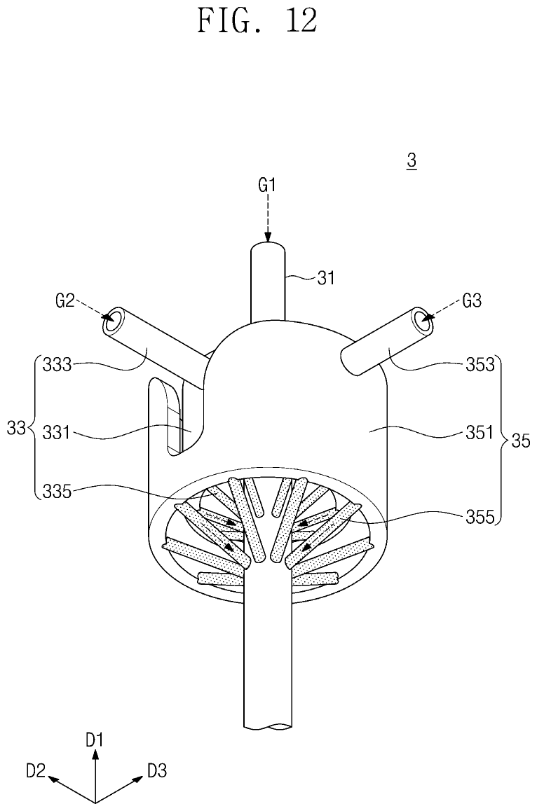

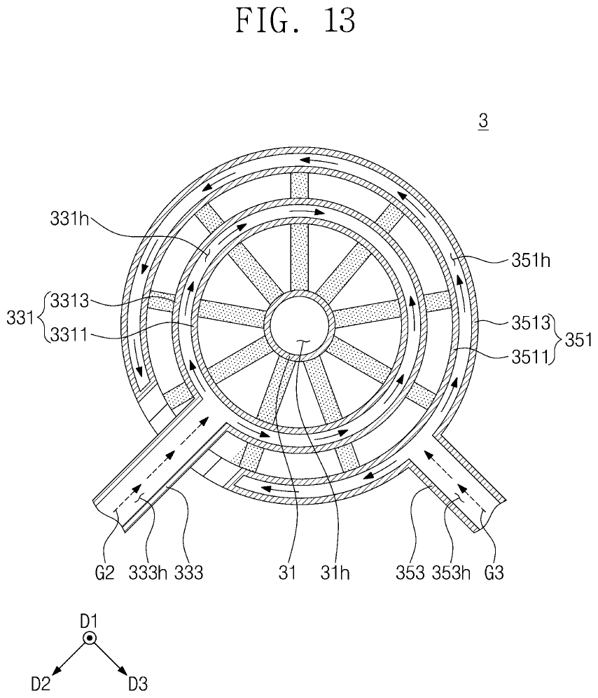

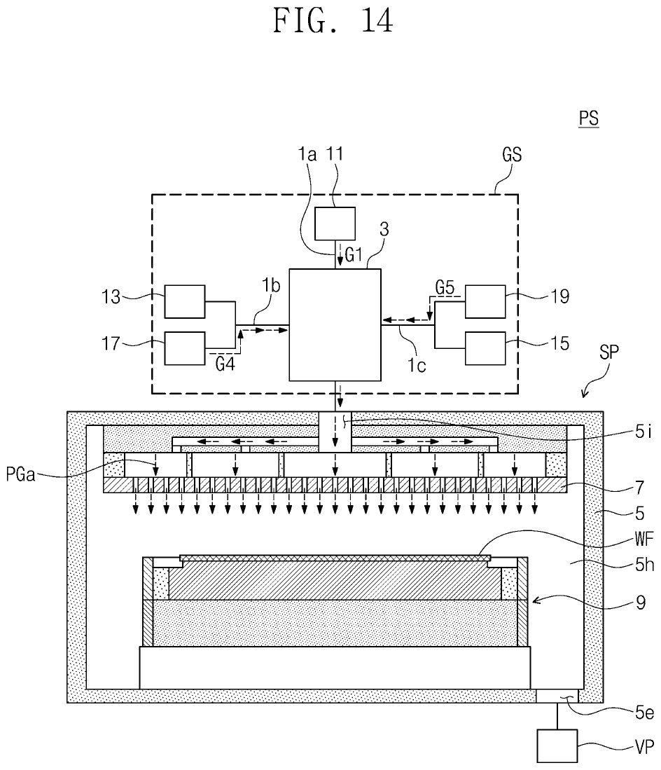

Hereinafter, the substrate processing method SS of FIG. 8 will be described in more detail with reference to FIGS. 9 to 15.

FIGS. 9 to 15 are diagrams illustrating a substrate processing method according to the flow chart of FIG. 8.

Referring to FIGS. 9 and 8, the disposing of the substrate in the substrate processing device (in S1) may include loading a substrate WF on the chuck 9. The chuck 9 may fasten the substrate WF to a specific position.

Referring to FIGS. 10, 11, 12, 13, and 8, the supplying of the first gas (in S211) may include supplying a first gas G1 from the first gas supplying device 11 to the gas mixing device 3. The first gas G1 may be injected into the main conduit 31.

The supplying of the second gas (in S212) may include supplying a second gas G2 from the second gas supplying device 13 to the gas mixing device 3. The second gas G2 may be injected into the main conduit 31 through the first gas transferring device 33. More specifically, the second gas G2 may be injected into the first distribution space 331h through the first supplying conduit 333. The second gas G2, which is injected into the first distribution space 331h, may be dispersed in a circumference direction along an outer side surface of the first inner cylinder 3311. Thereafter, the second gas G2 may be injected into the main conduit 31 along the first connection conduit 335.

The supplying of the third gas (in S213) may include supplying a third gas G3 from the third gas supplying device 15 the gas mixing device 3. The third gas G3 may be injected into the main conduit 31 through the second gas transferring device 35. More specifically, the third gas G3 may be injected into the second distribution space 351h through the second supplying conduit 353. The third gas G3, which is injected into the second distribution space 351h, may be dispersed in a circumference direction along the outer side surface of the second inner cylinder 3511. Thereafter, the third gas G3 may be injected into the main conduit 31 along the second connection conduit 355.

The mixing of the gases (in S214) may include mixing the second gas G2, which is injected into the main conduit 31, with the first gas G1. In addition, the third gas G3, which is injected into the main conduit 31, may be mixed with the first gas G1 and/or the second gas G2.

The supplying of the mixed gases to the space of the substrate (in S215) may include supplying a mixed gas PG to a space on the substrate WF through the shower head 7. The gas PG, which is supplied to the space on the substrate WF, may be used to form a deposition layer on the substrate WF.

Referring to FIGS. 14, 13, and 8, the supplying of the first gas (in S221) may include supplying the first gas G1 from the first gas supplying device 11 toward the gas mixing device 3. The first gas G1 may be injected into the main conduit 31.

The supplying of the fourth gas (in S222) may include supplying a fourth gas G4 from the fourth gas supplying device 17 toward the gas mixing device 3. The fourth gas G4 may be injected into the main conduit 31 through the first gas transferring device 33. More specifically, the fourth gas G4 may be injected into the first distribution space 331h through the first supplying conduit 333. The fourth gas G4, which is injected into the first distribution space 331h, may be dispersed in a circumference direction along the outer side surface of the first inner cylinder 3311. Thereafter, the fourth gas G4 may be injected into the main conduit 31 along the first connection conduit 335.

The supplying of the fifth gas (in S223) may include supplying a fifth gas G5 from the fifth gas supplying device 19 toward the gas mixing device 3. The fifth gas G5 may be injected into the main conduit 31 through the second gas transferring device 35. More specifically, the fifth gas G5 may be injected into the second distribution space 351h through the second supplying conduit 353. The fifth gas G5, which is injected into the second distribution space 351h, may be dispersed in a circumference direction along the outer side surface of the second inner cylinder 3511. Thereafter, the fifth gas G5 may be injected into the main conduit 31 along the second connection conduit 355.

The mixing of the gases (in S224) may include mixing the fourth gas G4, which is injected into the main conduit 31, with the first gas G1. In addition, the fifth gas G5, which is injected into the main conduit 31, may be mixed with the first gas G1 and/or the fourth gas G4.

The supplying of the mixed gases to the space on the substrate (in S225) may include supplying a mixed gas PGa to a space on the substrate WF through the shower head 7. The gas PGa, which is supplied to the space on the substrate WF, may be used to form a deposition layer on the substrate WE.

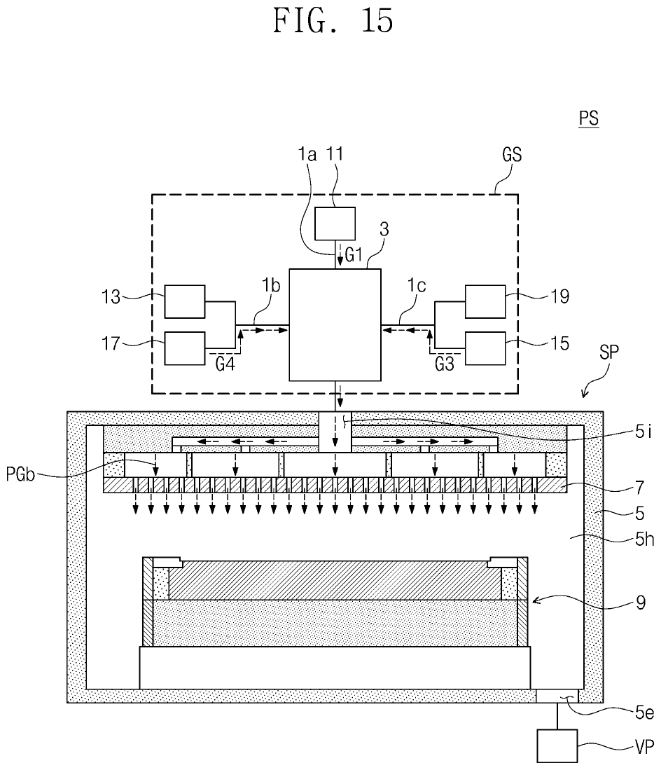

Referring to FIGS. 15 and 8, the substrate processing method SS may further include cleaning a substrate processing system. For the cleaning process, the first, third, and/or fourth gas supplying devices 11, 15 and/or 17 may be configured to supply the first, third, and/or fourth gases G1, G3 and/or G4, respectively. The first, third, and/or fourth gases G1, G3 and/or G4 may be used to form a gas PGb to clean the gas mixing device 3 and/or the substrate processing device SP.

In a gas mixing device according to some embodiments of the inventive concept, a substrate processing system including the same, and a substrate processing method using the same, it may be possible to effectively mix two or more gases. In particular, the two or more gases may be uniformly mixed with each other. Thus, a process on a substrate may be effectively performed.

In a gas mixing device according to some embodiments of the inventive concept, a substrate processing system including the same, and a substrate processing method using the same, it may be possible to prevent two or more reactive gases from being mixed with each other beforehand in a gas mixing device. More specifically, since a first distribution space is separated from a second distribution space, a second gas and a fifth gas may be prevented from being mixed with each other in the first distribution space and/or the second distribution space in a period when a process changes from a first mode to a second mode. Thus, it may be possible to prevent the two reactive gases from reacting with each other in at least one of the first and second distribution spaces and to prevent a particle formation issue from occurring. Since the particle formation issue is prevented, it may be possible to prevent the substrate from being damaged. In addition, a process of cleaning the gas mixing device may be more easily performed.

In a gas mixing device according to some embodiments of the inventive concept, a substrate processing system including the same, and a substrate processing method using the same, it may be possible to control the conductance or resistance properties of several conduits. For example, by separating a first distribution device from a main conduit, it may be possible to design a length of a conduction path or flow path, which connects the first distribution device to the main conduit, in a desired manner. In addition, a first gas transferring device and a second gas transferring device may be designed to have substantially the same or similar conductance. Accordingly, it may be possible to realize a smooth gas flow.

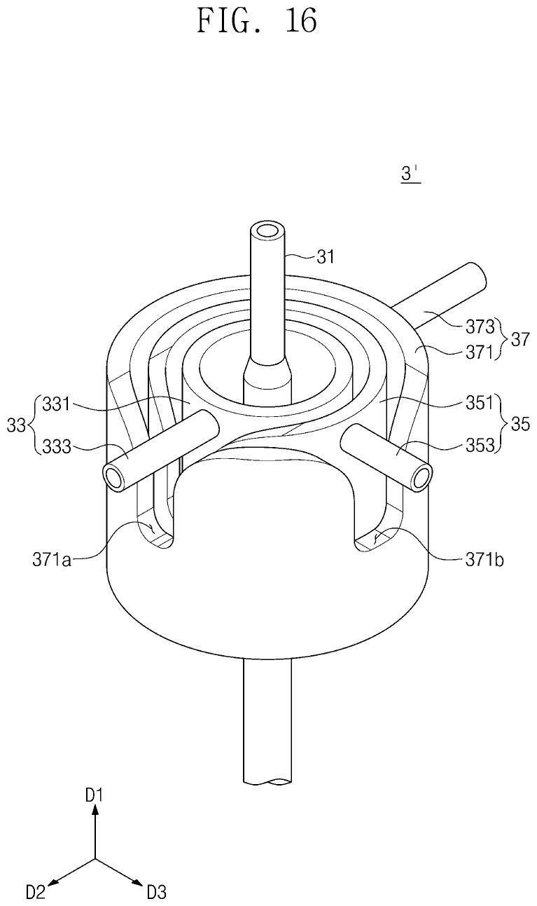

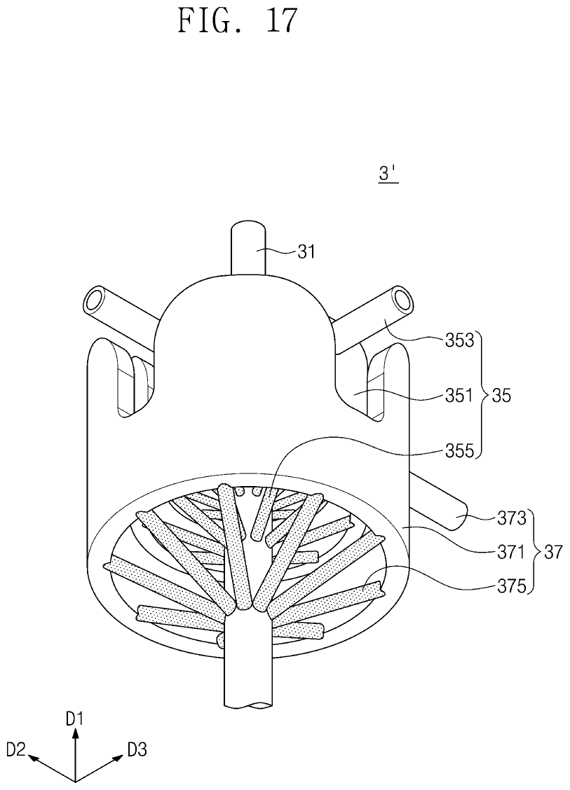

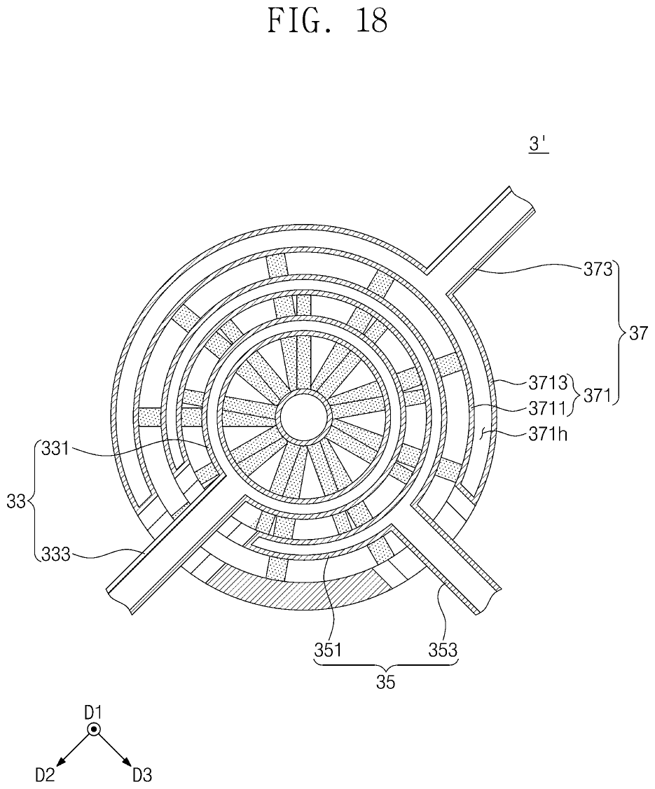

FIG. 16 is a perspective view illustrating a gas mixing device according to some embodiments of the inventive concept, FIG. 17 is a perspective view illustrating a gas mixing device according to some embodiments of the inventive concept, and FIG. 18 is a sectional view illustrating a gas mixing device according to some embodiments of the inventive concept.

In the following description, for concise description, an element previously described with reference to FIGS. 1 to 15 may be identified by the same reference number without repeating an overlapping description thereof.

Referring to FIGS. 16 to 18, a gas mixing device 3′ may be provided. The gas mixing device 3′ may further include a third gas transferring device 37. The third gas transferring device 37 may include a third distribution device 371, a third supplying conduit 373, and a third connection conduit 375.

The third distribution device 371 may include a third inner cylinder 3711 and a third outer cylinder 3713.

The third inner cylinder 3711 may be provided to at least partially enclose or surround the second outer cylinder 3513 (e.g., see FIG. 7). The third inner cylinder 3711 may be spaced apart from the second outer cylinder 3513 in a radial direction.

The third outer cylinder 3713 may be provided to at least partially enclose or surround the third inner cylinder 3711. The third outer cylinder 3713 may be spaced apart from the third inner cylinder 3711 in a radial direction.

A third distribution space 371h may be provided between the third outer cylinder 3713 and the third inner cylinder 3711.

The third distribution device 371 may further provide a first connection hole or slot 371a and a second connection hole or slot 371b. Each of the first and second connection holes 371a and 371b may be formed to have a shape that is recessed downward from a top surface of the third distribution device 371. The first supplying conduit 333 may be provided to penetrate or extend through the first connection hole 371a. The second supplying conduit 353 may be provided to penetrate or extend through the second connection hole 371b.

The third supplying conduit 373 may be coupled to an outer side surface of the third outer cylinder 3713. The third supplying conduit 373 may provide a third supplying path or channel. The third supplying path may be connected to the third distribution space 371h.

The third connection conduit 375 may connect the third distribution device 371 to the main conduit 31. In some embodiments, a plurality of third connection conduits 375 may be provided. The third connection conduit 375 may be arranged to be spaced apart from each other in a circumference direction.

In a gas mixing device according to some embodiments of the inventive concept, a substrate processing system including the same, and a substrate processing method using the same, it may be possible to mix four or more gases together at once.

In a gas mixing device according to some embodiments of the inventive concept, a substrate processing system including the same, and a substrate processing method using the same, it may be possible to effectively mix two or more gases.

In a gas mixing device according to some embodiments of the inventive concept, a substrate processing system including the same, and a substrate processing method using the same, it may be possible to prevent two or more gases from reacting with each other in a gas mixing device and prevent a particle formation issue.

In a gas mixing device according to some embodiments of the inventive concept, a substrate processing system including the same, and a substrate processing method using the same, it may be possible to uniformly supply a gas.

In a gas mixing device according to some embodiments of the inventive concept, a substrate processing system including the same, and a substrate processing method using the same, it may be possible to control conductance or resistance of a conduction path or flow path and achieve a smooth gas flow.

While example embodiments of the inventive concept have been particularly shown and described, it will be understood by one of ordinary skill in the art that variations in form and detail may be made therein without departing from the scope of the attached claims.

1. A gas mixing device, comprising:
a main conduit defining a main path extending in a first direction; and
a first gas transferring device connected to the main conduit,
wherein the first gas transferring device comprises:
a first distribution device surrounding the main conduit;
a first supplying conduit connected to the first distribution device and defining a first supplying path; and
a plurality of first connection conduits connecting the first distribution device to the main conduit,
wherein the first distribution device comprises:
a first inner cylinder surrounding the main conduit and spaced apart from the main conduit in a radial direction; and
a first outer cylinder surrounding the first inner cylinder and spaced apart from the first inner cylinder in a radial direction,
wherein a first distribution space is defined between the first inner cylinder and the first outer cylinder,
the first supplying conduit is coupled to the first outer cylinder, such that the first supplying path is connected to the first distribution space, and
the first connection conduits are spaced apart from each other in a circumferential direction.

2. The gas mixing device of claim 1, further comprising a second gas transferring device connected to the main conduit,
wherein the second gas transferring device comprises:
a second distribution device surrounding the first distribution device;
a second supplying conduit connected to the second distribution device and defining a second supplying path; and
a plurality of second connection conduits connecting the second distribution device to the main conduit,
wherein the second distribution device comprises:
a second inner cylinder surrounding the first outer cylinder and spaced apart from the first outer cylinder in a radial direction; and
a second outer cylinder surrounding the second inner cylinder and spaced apart from the second inner cylinder in a radial direction,
wherein a second distribution space is defined between the second inner cylinder and the second outer cylinder,
the second supplying conduit is coupled to the second outer cylinder, such that the second supplying path is connected to the second distribution space, and
the second connection conduits are spaced apart from each other in a circumferential direction.

3. The gas mixing device of claim 2, wherein the first supplying conduit is at substantially the same vertical level as the second supplying conduit.

4. The gas mixing device of claim 2, wherein a first height, which is a length of the first distribution space in the first direction, is smaller than a second height, which is a length of the second distribution space in the first direction.

5. The gas mixing device of claim 4, wherein an upper end of the first distribution device is located at substantially the same vertical level as an upper end of the second distribution device.

6. The gas mixing device of claim 2, wherein a vertical level of a lower end of each of the first connection conduits is higher than a vertical level of an upper end of each of the second connection conduits.

7. The gas mixing device of claim 2, wherein a diameter of each of the first connection conduits is smaller than a diameter of each of the second connection conduits.

8. The gas mixing device of claim 2, wherein the smallest horizontal distance between the first inner cylinder and the first outer cylinder is smaller than the smallest horizontal distance between the second inner cylinder and the second outer cylinder.

9. The gas mixing device of claim 2, wherein the second distribution device further includes a connection hole recessed downward from a top surface of the second distribution device, and
the first supplying conduit is connected to the first distribution device and extends through the connection hole.

10. The gas mixing device of claim 2, further comprising a third gas transferring device connected to the main conduit,
wherein the third gas transferring device comprises:
a third distribution device surrounding the second distribution device;
a third supplying conduit connected to the third distribution device and defining a third supplying path; and
a plurality of third connection conduits connecting the third distribution device to the main conduit,
wherein the third distribution device comprises:
a third inner cylinder surrounding the second outer cylinder and spaced apart from the second outer cylinder in a radial direction; and
a third outer cylinder surrounding the third inner cylinder and spaced apart from the third inner cylinder in a radial direction,
wherein a third distribution space is defined between the third inner cylinder and the third outer cylinder,
the third supplying conduit is coupled to an outer side surface of the third outer cylinder such that the third supplying path is connected to the third distribution space, and
the third connection conduits are spaced apart from each other in a circumferential direction.

11. The gas mixing device of claim 1, wherein a first height, which is a length of the first distribution space in the first direction, is equal to or larger than three times a first diameter, which is a diameter of the first supplying path.

12. The gas mixing device of claim 1, wherein each of the first connection conduits linearly extend from the first distribution device toward the main conduit, and
an extension direction of each of the first connection conduits is inclined at an acute angle relative to the first direction.

13. The gas mixing device of claim 1, wherein each of the first connection conduits is connected to a lower end of the first distribution space.

14. The gas mixing device of claim 1, wherein the number of the first connection conduits is eight.

15. The gas mixing device of claim 1, wherein the first supplying conduit is connected to an outer side surface of the first outer cylinder, and
an extension direction of the first supplying path is perpendicular to the first direction.

16. A gas mixing device, comprising:
a main conduit extending in a vertical direction; and
a first gas transferring device connected to the main conduit,
wherein the first gas transferring device comprises:
a first distribution device surrounding the main conduit;
a first supplying conduit connected to an outer side surface of the first distribution device and defining a first supplying path; and
a plurality of first connection conduits connecting the first distribution device to the main conduit,
wherein the first distribution device comprises:
a first inner cylinder surrounding the main conduit; and
a first outer cylinder surrounding the first inner cylinder and spaced apart from the first inner cylinder,
wherein a first distribution space is defined between the first inner cylinder and the first outer cylinder, and
a first height of the first distribution space is at least three times greater than a first diameter of the first supplying path.

17. The gas mixing device of claim 16, wherein a first injection hole, where the first supplying path and the first distribution space meet each other, is spaced apart from an upper end of the first distribution space, and
the first injection hole is at a higher vertical level than a center of the first distribution space.

18. A gas mixing device, comprising:
a main conduit connecting a first gas supplying device to a substrate processing device; and
a first gas transferring device connected to the main conduit,
wherein the first gas transferring device comprises:
a first distribution device surrounding the main conduit;
a first supplying conduit connecting a second gas supplying device to the first distribution device; and
a plurality of first connection conduits connecting the first distribution device to the main conduit,
wherein the first distribution device comprises:
a first inner cylinder surrounding the main conduit; and
a first outer cylinder surrounding the first inner cylinder and spaced apart from the first inner cylinder in a radial direction,
wherein the first connection conduits are spaced apart from each other in a circumferential direction.

19. The gas mixing device of claim 18, wherein the main conduit is connected to a space in or on a shower head of the substrate processing device.

20. The gas mixing device of claim 18, further comprising a second gas transferring device connected to the main conduit,
wherein the second gas transferring device comprises:
a second distribution device surrounding the first distribution device;
a second supplying conduit connecting a third gas supplying device to the second distribution device; and
a plurality of second connection conduits connecting the second distribution device to the main conduit,
wherein the second distribution device comprises:
a second inner cylinder surrounding the first outer cylinder; and
a second outer cylinder surrounding the second inner cylinder and spaced apart from the second inner cylinder in a radial direction.

21-25. (canceled)
